(19) United States
(12) Patent Application Publication
(10) Pub. No.: US 2008/0196927 A1
(43) Pub. Date: Aug. 21, 2008

(54) Working panel for multilayer printed circuit board

(75) Inventors: Jae Joon Lee, Gyunggi-do (KR); Han Kim, Gyunggi-do (KR); Il Soung Yoon, Gyunggi-do (KR); Seung Hyun Cho, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/004,421

(22) Filed: Dec. 21, 2007

(30) Foreign Application Priority Data
Feb. 16, 2007 (KR) 10-2007-0016528

(51) Int. Cl. H05K 1/00

(52) U.S. Cl. 174/250

(57) ABSTRACT

Disclosed is a working panel for a multilayer printed circuit board. The working panel for a multilayer printed circuit board is constructed in a manner such that first and second strips, having circuit layers and insulating layers which are layered on the upper and lower sides of a core in the opposite order with respect to each other, are appropriately disposed, by which the working panel can resist warpage due to thermal stress applied during the substrate fabrication process, thus imparting industrially useful effects that promise improvements in the standardization, productivity and yield of products.

### CROSS REFERENCE TO RELATED APPLICATION

This application claims the benefit of Korean Patent Application No. 10-2007-0016528, filed on Feb. 16, 2007, entitled “Working panel for multilayer printed circuit board”, which is hereby incorporated by reference in its entirety into this application.

### BACKGROUND OF THE INVENTION

1. Field of the Invention

The present invention relates, in general, to a working panel having a multilayer structure, which is adapted to be partitioned into a plurality of strips, each of which is comprised of a plurality of circuit substrates, and more particularly, to a working panel for a multilayer printed circuit board, in which first and second strips having circuits layers formed in the opposite order with respect to each other are appropriately disposed, thus preventing a warpage phenomenon by which the entire working panel warps in upper and lower directions, thereby increasing the standardization and yield of products.

2. Description of the Related Art

Generally, a printed circuit board (PCB) plays a role in connecting various electronic devices to one another in predetermined patterns, and, as a component widely used for all electronic products ranging from appliances including digital TV sets to intelligent communication systems, is classified into general-purpose PCBs, module PCBs, and package PCBs, depending on the end use thereof.

The PCB is fabricated by attaching a copper foil to one surface of an insulation plate made of phenol resin or epoxy resin, removing the portion of the copper foil other than the portion of the copper foil corresponding to a linear circuit through etching according to a circuit wiring pattern to thus form a necessary circuit, and then forming holes for attaching and mounting components. Depending on the number of wired circuit surfaces, there are single-sided PCBs, double-sided PCBs, and multilayer PCBs. As the number of layers increases, the PCB exhibits increased ability to have components mounted thereon, and is thus more useful for highly precise products. Recently, with the development of electronic industries, ultra-thin PCBs (thickness: 0.04˜0.2 mm) and multilayer circuit substrates have been widely employed.

The single-sided PCB is applied to relatively simple electronic systems. These days, however, the use of double-sided PCBs, in which circuits are formed on both surfaces thereof and connected to each other by through holes, or multilayer PCBs, in which circuits are formed not only on both surfaces but also into a plurality of layers, is increasing.

The multilayer PCB, which is typically known, is fabricated by impregnating a woven glass cloth with BT, FR-4, or another resin to thus prepare a core, which is an insulation plate, laminating copper foils on both surfaces of the core to form inner circuits, and then conducting a subtractive process or a semi-additive process.

The process of fabricating the multilayer PCB is briefly described below. First, inner circuit patterns are formed on both surfaces of the core through imaging. As such, as the core, useful is a CCL (Copper Clad Laminate), and the dielectric material for the CCL includes FR-4 or epoxy-based material, with which a woven glass cloth is impregnated.

After the formation of the inner circuit patterns, the substrate having the inner circuit patterns is subjected to CZ etching to roughen the surface of the core and the inner circuit patterns. Subsequently, on the substrate, in which the surface of the core and the inner circuit patterns is roughened, a thermosetting resin, which is a type of ink, is applied using a vacuum laminator, or a dry film type resin is attached to thus form outer insulating layers, thereby constructing a build-up layer.

Subsequently, in order to impart chemical resistance upon desmearing, heat is applied to the substrate having the build-up layer, thus pre-curing the outer insulating layers, and then through holes and via holes for the connection between the inner and outer layers are formed using a CNC drill or a laser drill.

Subsequently, residue is removed from the inner walls of the through holes and the via holes through desmearing, thus forming rough surfaces, after which surface roughness is formed using a CZ etchant. Then, through electroless copper plating and copper electroplating, metal layers are formed on the rough outer insulating layers, after which outer circuit patterns are formed through imaging. Then, a solder resist is applied on the outer surfaces of the outer circuit patterns.

The multilayer PCB is fabricated using a working panel 100, which is a substrate for packaging. As shown in FIG. 1, illustrating the working panel 100, strips 110, each of which includes a plurality of circuit substrate units, are arranged at equal intervals.

That is, the working panel 100 is a panel having a size of about 600 mm×600 mm. As seen in the drawing, the working panel is partitioned into a plurality of strips 110 having a predetermined size, and each of the strips 110 is partitioned into a plurality of circuit substrates on which electronic components are actually mounted.

FIG. 2 is a sectional view taken along the line A-A of FIG. 1. In the layer structure of the strip 110 according to a conventional technique, inner circuit patterns 113a, 113b, outer insulating layers 115a, 115b, outer circuit patterns 117a, 117b, and solder resist layers 119a, 119b are sequentially formed on the upper and lower surfaces of a core 111.

However, in the course of package fabrication, the conventional working panel for a multilayer PCB is exposed to external heat. Such heat causes a phenomenon in which the respective layers of the panel are deformed depending on the thermal expansion coefficient properties of materials therefor, undesirably incurring warpage of the entire working panel 100.

That is, the layers constituting the working panel 100 have different thermal expansion coefficients depending on the design and the type of material used. The difference in the thermal expansion coefficients of the layer materials increases as the size of the working panel becomes larger. Consequently, the process yield is decreased, and furthermore, the ability to mount components on the circuit substrate is hindered, resulting in very low product reliability.

### SUMMARY OF THE INVENTION

Accordingly, the present invention has been devised to solve the problems encountered in the related art, and provides a working panel for a multilayer PCB, in which first and second strips, having structures layered on the upper and lower sides of a core in the opposite order with respect to each other, are appropriately disposed to thus partially disperse and eliminate warping stress which is applied to the entire panel, thereby increasing the standardization and yield of products.

According to the present invention, a working panel for a multilayer PCB may include a plurality of first strips and a plurality of second strips arranged in a plane, each of which is partitioned into a plurality of circuit substrates, wherein each of the plurality of first strips has circuit layers having different circuit patterns from each other and layered on the upper and lower sides of a core in a predetermined order, and each of the plurality of second strips has circuit layers having different circuit patterns from each other and layered on the upper and lower sides of a core in an opposite order with respect to the circuit layers of the first strip.

In the working panel for a multilayer PCB, each of the first strips may include positive and negative circuit layers having different circuit patterns from each other respectively formed on the upper and lower sides of the core, positive and negative insulating layers respectively formed on the outer surfaces of the positive and negative circuit layers, and outermost solder resist layers, and each of the second strips may include negative and positive circuit layers having different circuit patterns from each other respectively formed on the upper and lower sides of the core, negative and positive insulating layers respectively formed on the outer surfaces of the negative and positive circuit layers, and outermost solder resist layers.

In the working panel for a multilayer PCB, the first strips and the second strips may be alternately arranged.

In the working panel for a multilayer PCB, two or more of the first strips, which are disposed adjacent to each other, may constitute a first strip group, and two or more of the second strips, which are disposed adjacent to each other, may constitute a second strip group, wherein the first and second strip groups may be alternately arranged.

In the working panel for a multilayer PCB, two or more of the first strips, which are disposed adjacent to each other, may constitute a first strip group, and two or more of the second strips, which are disposed adjacent to each other, may constitute a second strip group, wherein one of the first and second strip groups may be disposed in the center of the working panel, and the other of the first and second strip groups may be equally divided and symmetrically disposed on both lateral sides of the working panel.

In the working panel for a multilayer PCB, the positive and negative circuit layers may have copper contents or weights different from each other.

In the working panel for a multilayer PCB, the positive and negative insulating layers may be formed of materials having different thermal expansion coefficients.

### BRIEF DESCRIPTION OF THE DRAWINGS

The features and advantages of the present invention will be more clearly understood from the following detailed description, taken in conjunction with the accompanying drawings, in which:

FIG. 1 is a view illustrating the strip arrangement of a working panel according to a conventional technique;

FIG. 2 is a sectional view taken along the line A-A of FIG. 1;

FIG. 3 is a view illustrating the strip arrangement of a working panel according to a first embodiment of the present invention;

FIG. 4 is a sectional view taken along the line B-B of FIG. 3;

FIG. 5 is a sectional view taken along the line C-C of FIG. 3;

FIG. 6 is a view illustrating the strip arrangement of a working panel according to a second embodiment of the present invention; and

FIG. 7 is a view illustrating the strip arrangement of a working panel according to a third embodiment of the present invention.

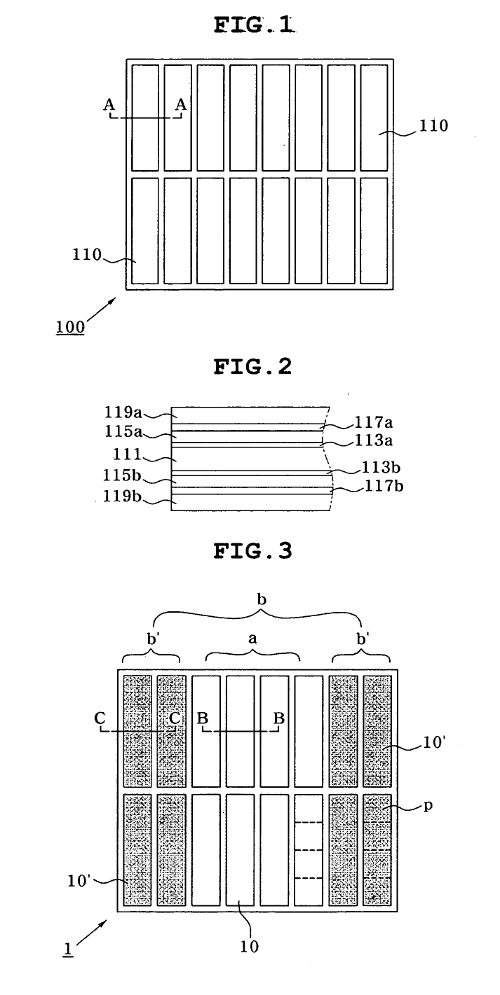

### DESCRIPTION OF THE PREFERRED EMBODIMENTS

Unless otherwise defined, all terms used herein have the same meaning as commonly understood by one having ordinary skill in the art to which the present invention belongs. It will be further understood that terms, such as those defined in commonly used dictionaries, should be interpreted as having meanings consistent with their meanings in the context of the relevant art, and are not to be interpreted in an idealized or overly formal sense unless expressly so defined herein.

Hereinafter, a detailed description will be given of a working panel for a multilayer PCB, according to the preferred embodiments of the present invention, with reference to the appended drawings.

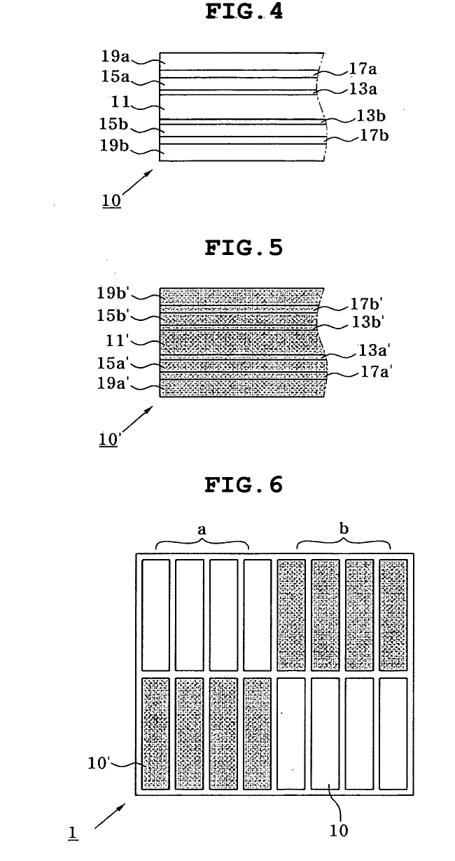

FIG. 3 is a view illustrating the strip arrangement of a working panel according to a first embodiment of the present invention, FIG. 4 is a sectional view taken along the line B-B of FIG. 3, and FIG. 5 is a sectional view taken along the line C-C of FIG. 3.

As shown in the drawings, the working panel 1 for a multilayer PCB, according to the first embodiment of the present invention, is partitioned into a plurality of strips, which are arranged at equal intervals in a plane, and each of the strips is partitioned into a plurality of circuit substrate units p on which electronic components are substantially mounted.

The working panel 1, which is partitioned into the plurality of strips, is constructed similarly to a conventional working panel. However, the working panel 1 according to the present invention is characterized in that a plurality of first strips 10 and a plurality of second strips 10′, having structures layered in the opposite order with respect to each other, are provided and appropriately disposed so as to eliminate warpage due to heat which is applied during the substrate fabrication process.

The first strip 10 is structured in a manner such that positive and negative circuit layers 13a, 13b having different circuit patterns from each other are respectively formed on the upper and lower sides of a core 11, positive and negative insulating layers 15a, 15b are respectively formed on the outer surfaces of the positive and negative circuit layers 13a, 13b, and a solder resist is applied on the outer surfaces of outermost circuit layers, thus forming solder resist layers 19a, 19b.

Because the circuit patterns of the positive and negative circuit layers 13a, 13b are different from each other, differences in the weights and copper contents thereof exist. The positive and negative circuit layers 13a, 13b and the positive and negative insulating layers 15a, 15b may be alternately layered. The positive and negative insulating layers 15a, 15b may be formed of materials having different thermal expansion coefficients.

The formation of the circuit layers, the insulating layers, and the solder resist layers on the upper and lower sides of the core 11 is carried out through a known technique, and a detailed description thereof is omitted.

In the present invention, with the intention of understanding the layer structure of the first strip 10, a structure having four circuit layers is illustrated in FIG. 4.

As shown in the drawing, in the first strip 10, the positive circuit layer 13a is formed on the upper side of the core 11, and the negative circuit layer 13b is formed on the lower side of the core 11. On the outer surface, preferably, the upper surface, of the positive circuit layer 13a, the positive insulating layer 15a is formed, whereas the negative insulating layer 15b is formed on the lower surface of the negative circuit layer 13b. Further, the positive outer circuit layer 17a is formed on the outer surface of the positive insulating layer 15a, whereas the negative outer circuit layer 17b is formed on the outer surface of the negative insulating layer 15b. Furthermore, the solder resist layers 19a, 19b are formed on the outer surfaces of the positive and negative outer circuit layers 17a, 17b, respectively.

The second strip 10′ has a structure layered in the opposite order with respect to that of the first strip 10. Specifically, negative and positive circuit layers 13b′, 13a′ having circuit patterns different from each other are respectively formed on the upper and lower sides of a core 11′, which is an insulator, and negative and positive insulating layers 15b′, 15a′ are respectively formed on the outer surfaces of the negative and positive circuit layers 13b′, 13a′, and furthermore, a solder resist is applied on the outer surfaces of outermost circuits layers, thus forming solder resist layers 19b′, 19a′.

As in the aforementioned first strip 10, the circuit patterns of the negative and positive circuit layers 13b′, 13a′ are formed to be different from each other, and thereby differences in the weights and copper contents thereof exist, leading to different thermal expansion coefficients. The negative and positive insulating layers 15b′, 15a′ may be formed of materials having different thermal expansion coefficients. For the insulating layers, any material may be used so long as it is known in the art, and a detailed description thereof is omitted.

In addition, with the intention of understanding the layer structure of the second strip 10′, a structure having four circuit layers is illustrated in FIG. 5.

As shown in the drawing, in the second strip 10′, the negative circuit layer 13b′ is formed on the upper side of the core 11′, whereas the positive circuit layer 13a′ is formed on the lower side of the core 11′. Further, on the outer surface, preferably, the upper surface, of the negative circuit layer 13b′, the negative insulating layer 15b′ is formed, whereas the positive insulating layer 15a′ is formed on the lower surface of the positive circuit layer 13a′. Furthermore, the negative outer circuit layer 17b′ is formed on the upper surface of the negative insulating layer 15b′, whereas the positive outer circuit layer 17a′ is formed on the lower surface of the positive insulating layer 15a′. Moreover, the solder resist layers 19b′, 19a′ are formed on the outer surfaces of the negative and positive outer circuit layers 17b′, 17a′, respectively.

As such, the first strip 10 and the second strip 10′ are actually composed of the same layers, except that the layers thereof are layered in the opposite order with respect to each other.

Specifically, in the second strip 10′, the core 11′, the positive circuit layer 13a′, the negative circuit layer 13b′, the positive insulating layer 15a′, the negative insulating layer 15b′, the positive outer circuit layer 17a′, and the negative outer circuit layer 17b′ correspond to the core 11, the positive circuit layer 13a, the negative circuit layer 13b, the positive insulating layer 15a, the negative insulating layer 15b, the positive outer circuit layer 17a, and the negative outer circuit layer 17b, in the first strip 10. Thus, the first and second strips are substantially the same as each other.

In the working panel 1 thus constructed, according to the present invention, the first strips 10 and the second strips 10′ have structures layered in the opposite order with respect to each other, thus making it possible to prevent warpage, and furthermore, for more effective prevention, the following arrangement of the first strips 10 and the second strips 10′ is suggested.

As illustrated in FIG. 3, in the working panel 1, the plurality of first strips 10, preferably, two or more of the first strips 10, which are disposed adjacent to each other, may constitute a first strip group a, and two or more of the second strips 10′, which are disposed adjacent to each other, may constitute a second strip group b.

In this case, the first strip group a is disposed in the center of the panel, and the second strip group b is equally divided into second strip subgroups b′, which are then symmetrically disposed on both lateral sides thereof, as seen in the drawing.

Thereby, warpage of the entire working panel due to thermal stress which is applied during the substrate fabrication process may be prevented. Because the first strips 10 and the second strips 10′ have structures layered in the opposite order with respect to each other, the thermal expansion coefficients of the circuit layers or the insulating layers, disposed in a common plane, are different. Thus, warpage due to thermal stress applied during the substrate fabrication process is generated in opposite directions by the first strips 10 and the second strips 10′, and consequently the entire working panel 1 is prevented from warping in any one direction.

FIG. 6 is a view illustrating the arrangement of first strips 10 and second strips 10′ of a working panel 1, according to a second embodiment of the present invention. As shown in the drawing, in the working panel 1 according to the second embodiment of the present invention, the plurality of first strips 10, which are disposed adjacent to each other, may constitute a first strip group a, and two or more of the second strips 10′, which are disposed adjacent to each other, may constitute a second strip group b. In this case, the first and second strip groups a, b are alternately disposed as shown in the drawing.

In the case where the number of strips, which are arranged in the upper and lower two rows of the working panel 1, is 16, the first strip group a, having four adjacent first strips, and the second strip group b, having four adjacent second strips, are disposed in the upper row of the panel, and the second strip group b, having four adjacent second strips, and the first strip group a, having four adjacent first strips, are disposed in the lower row thereof. This strip arrangement may vary appropriately depending on the increase or decrease in the number of strips.

The working panel 1 having the strips thus arranged may resist warpage due to thermal stress applied during the substrate fabrication process, as mentioned above. Specifically, because the first strips 10 and the second strips 10′ have structures layered in the opposite order, the thermal expansion coefficients of the circuit layers or the insulating layers, disposed in a common plane, are different. Therefore, warpage due to thermal stress during the substrate fabrication process is generated in opposite directions by the first strips 10 and the second strips 10′. Consequently, the entire working panel 1 is prevented from warping in any one direction.

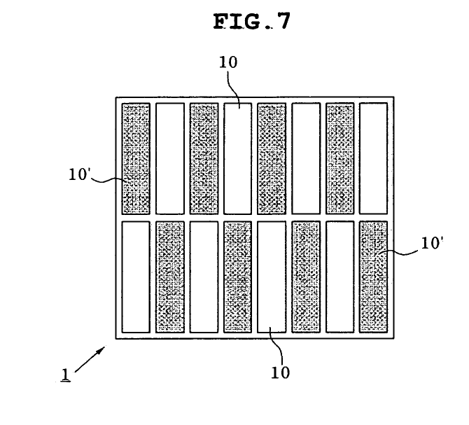

FIG. 7 is a view illustrating the arrangement of first strips 10 and second strips 10′ of a working panel 1, according to a third embodiment of the present invention. As shown in the drawing, in the working panel 1 according to the third embodiment of the present invention, the first strips 10 and the second strips 10′ are alternately arranged.

The working panel 1 having the strips thus arranged may resist warpage due to thermal stress applied during the substrate fabrication process, as mentioned above. Because the first strips 10 and the second strips 10′ have structures layered in the opposite order, the thermal expansion coefficients of the circuit layers or the insulating layers, disposed in a common plane, are different. Accordingly, warpage due to thermal stress during the substrate fabrication process is generated in opposite directions by the first strip 10 and the second strip 10′, and thus the entire working panel 1 is prevented from warping in any one direction.

As described hereinbefore, the present invention provides a working panel for a multilayer PCB. According to the present invention, the working panel for a multilayer PCB is constructed in a manner such that first and second strips, having circuit layers and insulating layers which are layered on the upper and lower sides of a core in the opposite order with respect to each other, are appropriately disposed, and thereby the working panel can resist warpage due to thermal stress applied during the substrate fabrication process, thus imparting industrially useful effects promising improvements in the standardization, productivity and yield of products.

The first strips and the second strips have structures layered in the opposite order with respect to each other, by which warpage due to thermal stress is generated in opposite directions. Accordingly, warping stress, which is applied to the entire working panel, is intended to be dispersed and eliminated, advantageously decreasing the defect rates of products and increasing the reliability of products.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A working panel for a multilayer printed circuit board, comprising a plurality of first strips and a plurality of second strips arranged in a plane, each of which is partitioned into a plurality of circuit substrates, wherein each of the plurality of first strips has circuit layers having different circuit patterns from each other and layered on upper and lower sides of a core in a predetermined order, and each of the plurality of second strips has circuit layers having different circuit patterns from each other and layered on upper and lower sides of a core in an opposite order with respect to the circuit layers of the first strip.

2. The working panel as set forth in claim 1, wherein each of the first strips comprises positive and negative circuit layers having different circuit patterns from each other respectively formed on the upper and lower sides of the core, positive and negative insulating layers respectively formed on outer surfaces of the positive and negative circuit layers, and outermost solder resist layers, and
each of the second strips comprises negative and positive circuit layers having different circuit patterns from each other respectively formed on the upper and lower sides of the core, negative and positive insulating layers respectively formed on outer surfaces of the negative and positive circuit layers, and outermost solder resist layers.

3. The working panel as set forth in claim 1, wherein the first strips and the second strips are alternately arranged.

4. The working panel as set forth in claim 1, wherein two or more of the first strips, which are disposed adjacent to each other, constitute a first strip group, and two or more of the second strips, which are disposed adjacent to each other, constitute a second strip group, wherein the first and second strip groups are alternately arranged.

5. The working panel as set forth in claim 1, wherein two or more of the first strips, which are disposed adjacent to each other, constitute a first strip group, and two or more of the second strips, which are disposed adjacent to each other, constitute a second strip group, wherein one of the first and second strip groups is disposed in a center of the working panel, and the other of the first and second strip groups is equally divided and symmetrically disposed on both lateral sides of the working panel.

6. The working panel as set forth in claim 2, wherein the positive and negative circuit layers have copper contents or weights different from each other.

7. The working panel as set forth in claim 2, wherein the positive and negative insulating layers comprise materials having different thermal expansion coefficients.
